(19) United States
(12) Patent Application Publication
(10) Pub. No.: US 2010/0144147 A1
(43) Pub. Date: Jun. 10, 2010

(54) SAMPLE HOLDING TOOL, SAMPLE SUCTION DEVICE USING THE SAME AND SAMPLE PROCESSING METHOD USING THE SAME

(75) Inventors: Takeshi Muneishi, Shiga (JP); Katsuya Okumura, Tokyo (JP)

Correspondence Address: HOGAN & HARTSON L.L.P., 1999 AVENUE OF THE STARS, SUITE 1400, LOS ANGELES, CA, 90067, US

(73) Assignees: KYOCERA CORPORATION, Kyoto-shi, Kyoto (JP); OKUTEC CO., LTD, Tokyo (JP)

(21) Appl. No.: 11/996,938

(22) PCT Filed: Jul. 28, 2006
(86) PCT No.: PCT/JP2006/315042

§ 371 Date: Mar. 2, 2010

(30) Foreign Application Priority Data
Jul. 28, 2005 (JP) 2005-218225

(51) Int. Cl. H01L 21/683; H02N 13/00; H01L 21/30; B05C 13/02; B23Q 3/15; B23B 31/28

(52) U.S. Cl. 438/689; 156/345.51; 118/500; 269/289 R; 279/128; 257/E21.219

(57) ABSTRACT

A sample holding tool is provided with a base plate, a plurality of convex portions formed on the base plate so as to stick out from the upper face thereof; and at least one holding plate having a plurality of curved face portions corresponding to the convex portions, with a lower face concave portion of each of the curved face portions being made in contact with the tip portion of each of the convex portions, so that a sample is supported on the upper face convex portion of each of the curved face portions; thus, since the sample is supported by the curved face portion of the holding plate, the contact area to the sample is made very small so that it becomes possible to greatly reduce pointed peak portions, scratches and the like at contact portions between the sample and the curved face portions. Consequently, generation of particles due to abrasion of the sample can be reduced and the particles are reduced from intruding into scratches and voids and occasionally readhering to the sample.

### FIELD OF THE INVENTION

The present invention relates to a sample holding tool that is used in a manufacturing process of a sample, such as a semiconductor wafer used for manufacturing a semiconductor and a liquid crystal plate used for liquid crystal manufacturing processes, so as to transport such a sample, and also concerns a sample suction device using such a tool and a sample processing method using such a sample suction device.

### BACKGROUND OF THE INVENTION

In a manufacturing process for a semiconductor, a sample, such as a semiconductor wafer made from silicon or the like, is supported on sample plates of manufacturing devices and inspection devices several times. With respect to a method for holding a sample on the sample plate, various devices and holding methods have been proposed depending on the kinds of the manufacturing processes. Processes, which are carried out with the sample being held, include, for example, a process for polishing the sample so as to have a mirror surface without any scratches, a process used for partially exposing a photosensitive material referred to as resist, applied onto the sample by light rays or electron beam with the wavelengths thereof being adjusted, a process for removing the exposed resist and a process for inspecting the sample that have been subjected to the respective processes. Moreover, with respect to the ambient atmosphere of the sample plate holding the sample, in addition to the atmosphere, a special gas atmosphere, such as nitrogen and oxygen, and various other atmospheres may be used, with its pressure also ranging variously from 1×10⁵ Pa corresponding to the atmospheric pressure to 1×10⁻⁷ Pa referred to as high vacuum.

In the conventional sample suction device, in response to these processes of many kinds and various modes of atmospheres, materials having a high corrosion resistance are selected as the material for the sample holding tool, and the functional force used for holding the sample is selected from a mechanical force such as a spring force, a pressure difference force of gases and an electrostatic force.

However, recently, in the semiconductor manufacturing apparatuses, along with further miniaturization and high integration, various problems, such as particles that are generated by frictional abrasion occurring between a sample and a sample holding tool upon holding the sample, and adhere to the sample, and particles that are intruded into scratches and the like located on the surface of the sample holding tool, and re-adhere to the sample due to an external force such as vibrations, have been raised.

In order to solve these problems, conventionally, the following methods have been taken: the contact area between a sample and the sample holding tool is made smaller so that abrasion is reduced, the edge of the contact portion to the sample is chamfered into a curved shape, and scratches and voids on the surfaces of a sample holding tool at contact portions and portions other than the contact portions are polished by using abrasive grains or ultrasonic waves.

For example, Patent Document 1 has proposed a vacuum suction device in which a concave portion is formed on one main face of a base plate made from ceramics, with a plurality of protrusions are formed on the bottom face of the concave portion. This describes that these protrusions have a shape in which a truncated cone, truncated pyramid or a semi-spherical shape that is narrowed from the base toward the tip, or columns having different diameters are piled up, so that the tip face of each protrusion is made as small as possible or the width of the tip face is set to 0.1 mm, and that consequently, generation of particles and contamination due to contact to the sample can be greatly reduced.

Moreover, Patent Document 2 has proposed a sample suction device in which a sample securing face that holds a sample is provided with protrusions or grooves to be shaped into a concave/convex face so that the top face and side faces of each convex portion of the concave/convex face and the bottom face of each concave portion of the concave/convex face are commonly polished. This sample suction device features that the peripheral edge of the convex portion has a curved line shape in its cross section, and that scratches and voids located on the concave portion are removed. With respect to the effects, it describes that pointed peak portions are reduced at contact portions between the sample securing face and the sample so that generation of particles due to abrasion is restrained, and that re-adhering to the sample is reduced with respect to the particles through scratches and voids due to an external force exerted upon attaching and detaching the sample to and from the device.

Furthermore, Patent Document 3 has proposed a structure in which a DLC (Diamond like Carbon) film is formed on the surface of a base plate with a thickness of 3 to 40 μm, and describes that the film thus formed covers defects and pointed peak portions of the base plate to reduce generation of particles due to abrasion of a sample at the pointed peak portions.

### Patent Document 1: Japanese Unexamined Patent Publication No. 10-242255

### Patent Document 2: Japanese Unexamined Patent Publication No. 2003-86664

### Patent Document 3: Japanese Unexamined Patent Publication No. 2005-101247

### DISCLOSURE OF THE INVENTION

### Problems to be Solved by the Invention

In the sample holding tool of the above-mentioned related art, however, since the area of the tip face is made smaller or since the width of the tip face is set to as small as 0.1 mm, for example, in Patent Document 1, many processes are required for production and in the manufacturing processes, with the result that there is a limitation in machining the contact area of the contact portions to such a small area.

Moreover, Patent Document 2 has described that the two corners of the peripheral edge of the convex portion are processed into a smooth curved line shape in its cross section by using a process such as polishing with abrasive grains so that pointed peak portions are reduced in the contact portions to the sample and the generation of particles due to sample abrasion is consequently suppressed; however, it is very difficult to completely eliminate such pointed peak portions and scratches to which particles are allowed to intrude, from the surface of the base plate having many fine convex portions by using the above-mentioned process, and there is also a limitation in restraining the generation of particles due to sample abrasion in the border portion between the flat portion of the convex portion and the peripheral edge corner portion.

Moreover, although Patent Document 3 describes that by forming a DLC (Diamond like Carbon) film having a film thickness of 3 to 40 μm on a base plate surface, pointed peak portions and scratches on the base plate are covered so that the generation of particles can be restrained, the flatness of the sample holding portion of the base plate deteriorates to the extent corresponding to the film thickness, whereby the sample is not held correctly.

The objective of the present invention is to provide a sample holding tool that can reduce generation of particles due to sample abrasion and also reduce particles from intruding into scratches and voids and occasionally re-adhering to the sample, and a sample suction device using such a tool, as well as a sample processing method using such a sample suction device.

### Means to Solve the Problems

In order to solve the above-mentioned problems, the present inventors have made extensive and intensive studies and as a result have found effective solutions having the following arrangements, thereby completing the present invention.

(1) A sample holding tool that is provided with: a base plate; a plurality of convex portions formed on the base plate so as to stick out from the upper face thereof; and at least one holding plate having a plurality of curved face portions corresponding to the convex portions, with a lower face concave portion of each of the curved face portions being made in contact with the tip portion of each of the convex portions, so that a sample is supported on the upper face convex portion of each of the curved face portions.

(2) The sample holding tool, described in the above-mentioned (1), in which a guide plate having a plurality of through holes corresponding to the convex portions is placed on the upper face of the base plate.

(3) The sample holding tool, described in the above-mentioned (1), in which the base plate and the holding plate are provided with evacuation holes that communicate with a space between the sample and the holding plate.

(4) The sample holding tool, described in the above-mentioned (2), in which the base plate, the holding plate and the guide plate are provided with evacuation holes that communicate with a space between the sample and the holding plate.

(5) The sample holding tool, described in any of the above-mentioned (1) to (4), in which a void portion, formed by the convex portion and the holding plate, is filled with a joining material.

(6) The sample holding tool, described in any of the above-mentioned (1) to (5), in which the lower face concave portion of each of the curved face portions of the holding plates has a curvature radius that is larger than the curvature radius at the tip portion of each of the convex portions.

(7) The sample holding tool, described in any of the above-mentioned (1) to (6), in which the convex portion has an arc shaped cross section in at least its tip portion.

(8) The sample holding tool, described in the above-mentioned (7), in which the convex portion has a spherical cap shape.

(9) The sample holding tool, described in the above-mentioned (7), in which the convex portion has an annular shape.

(10) The sample holding tool, described in any of the above-mentioned (1) to (9), in which the holding plate has a surface roughness of 0.2 μm or less in the average interval (S) of local peaks at least on the surface on the side supporting the sample.

(11) The sample holding tool, described in any of the above-mentioned (1) to (10), in which the holding plate is comprised of a monocrystal or amorphous ceramic body.

(12) The sample holding tool, described in any of the above-mentioned (1) to (11), in which the base plate is comprised of a ceramic body.

(13) The sample holding tool, described in any of the above-mentioned (1) to (12), in which the convex portion is comprised of a ceramic body.

(14) A sample suction device, which uses the sample holding tool described in any of the above-mentioned (1) to (13), provided with: a seal portion that is placed on an outer edge of the base plate upper face, and used for forming a tightly closed space between the sample and the holding plate; and evacuation means for evacuating the space so that the sample is sucked by a pressure difference from the outside of the space.

(15) A sample suction device, which uses the sample holding tool described in any of the above-mentioned (1) to (13), provided with: an electrode unit that is formed on the surface on the base plate side of the holding plate so that the sample is sucked by an electrostatic force generated between the holding plate and the sample.

(16) A sample processing method, which uses the sample suction device described in the above-mentioned (14) or (15), provided with the steps of: sucking the sample so as to be placed on the holding plate, and carrying out a process, such as etching or film-forming; on the sample.

### EFFECTS OF THE INVENTION

In accordance with the sample holding tool of the present invention, since a sample is supported by a curved face portion of a holding plate having a smooth surface, the contact area to the sample can be made very small so that it becomes possible to greatly reduce pointed peak portions, scratches and the like at contact portions between the sample and the curved face portions. Consequently, generation of particles due to abrasion of the sample can be reduced and the particles are reduced from intruding into scratches and voids and occasionally re-adhering to the sample.

### BRIEF DESCRIPTION OF THE DRAWINGS

FIG. 1 is a perspective view that shows a sample holding tool in accordance with a first embodiment of the present invention.

FIG. 2(a) is a cross-sectional view that shows the sample holding tool of FIG. 1 on which a sample is placed, and FIG. 2(b) is an enlarged cross-sectional view showing one portion of FIG. 2(a).

FIG. 3 is a drawing that shows a sample holding tool in accordance with a second embodiment of the present invention, FIG. 3(a) is a cross-sectional view that shows a state in which a sample is placed on the sample holding tool, and FIG. 3(b) is an enlarged view showing one portion of FIG. 3(a).

FIG. 4 is a perspective view that shows a sample holding tool in accordance with a third embodiment of the present invention.

FIG. 5(a) is a cross-sectional view that shows the sample holding tool of FIG. 4 on which a sample is placed, and FIG. 5(b) is an enlarged cross-sectional view showing one portion of FIG. 5(a).

FIGS. 6(a), (b), (c), (d) and (e), which are drawings that show various embodiments of a convex portion, and FIGS. 6(a), 6(b) and 6(d) are cross-sectional views, FIG. 6(c) is a perspective view, and FIG. 6(e) is a partially exploded perspective view.

FIG. 7 is a cross-sectional view of a sample holding tool on which a sample is placed, in accordance with a fourth embodiment of the present invention.

FIG. 8 is a cross-sectional view of a sample holding tool on which a sample is placed, in accordance with a fifth embodiment of the present invention.

FIG. 9 is a cross-sectional view showing a sample suction device in which the sample holding tool of the present invention is used.

FIG. 10 is a cross-sectional view showing a sample suction device in accordance with another embodiment, in which the sample holding tool of the present invention is used.

### PREFERRED EMBODIMENTS FOR CARRYING OUT THE INVENTION

The following description will discuss an embodiment of a sample holding tool of the present invention.

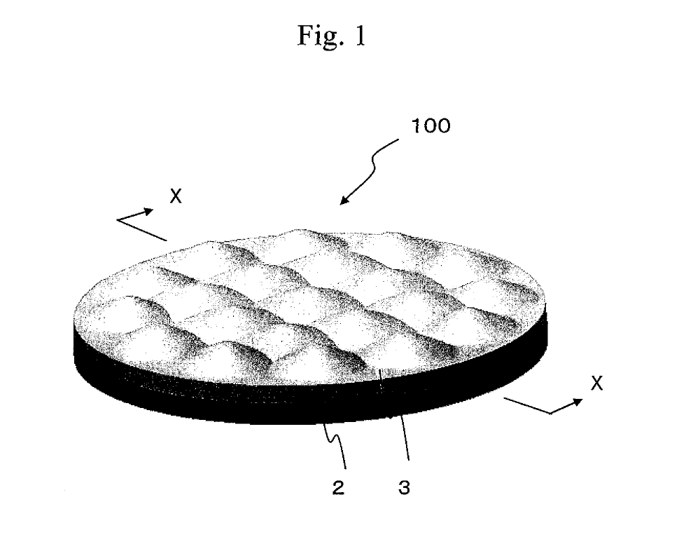

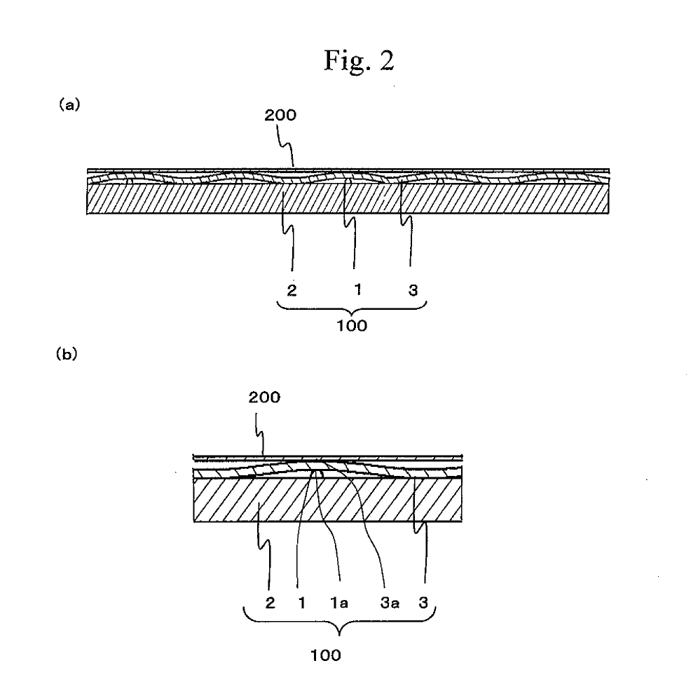

FIG. 1 is a perspective view showing a sample holding tool according to the embodiment, FIG. 2(a) is a cross-sectional view taken along the line X-X in FIG. 1, and FIG. 2(b) is an enlarged cross-sectional view showing one portion of FIG. 2(a) .

As shown in FIGS. 1 and 2, a sample holding tool 100 according to the embodiment is provided with a base plate 2 having a plurality of convex portions 1 on its main face (upper face) on the upper side and at least one holding plate 3 having a curved face portion with which a tip portion 1a of each of the convex portions 1 is made in contact, placed on its lower face concave portion, and in FIGS. 1 and 2, a single holding plate 3 having a plurality of curved face portions is shown (First Embodiment).

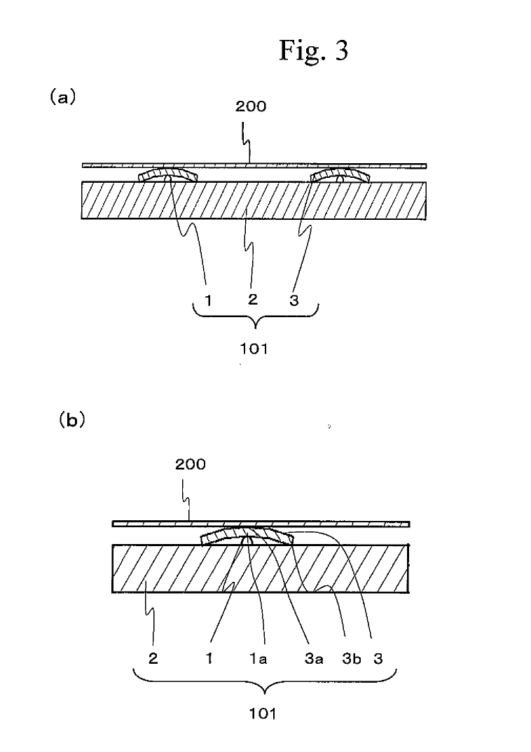

Moreover, FIGS. 3(a) and 3(b) show a sample holding tool 101 having a plurality of holding plates 3, and FIG. 3(a) is a cross-sectional view taken in a direction perpendicular to the main face of the base plate, and FIG. 3(b) is an enlarged cross-sectional view showing one portion of FIG. 3(a) (Second Embodiment).

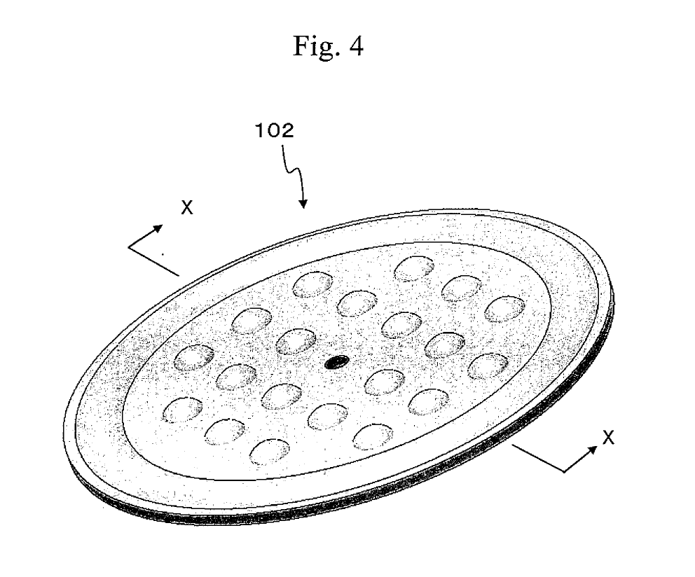

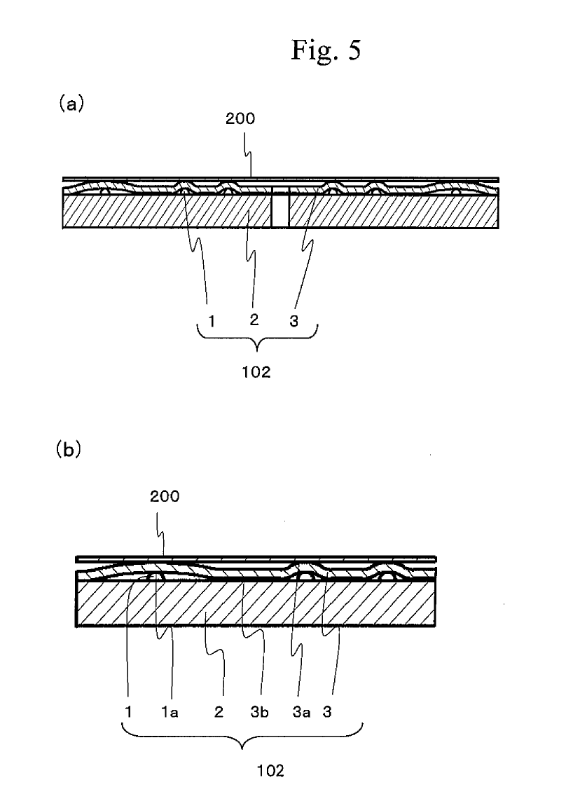

Furthermore, FIG. 4 is a perspective view showing a sample holding tool 102 according to the embodiment, FIG. 5(a) is a cross-sectional view taken along the line X-X in FIG. 4, and FIG. 5(b) is an enlarged cross-sectional view showing one portion of FIG. 5(a). As shown in FIGS. 4 and 5, a sample holding tool 102 according to the embodiment is provided with a single holding plate 3 having an annular shaped curved face portion and a plurality of curved face portions, and convex portions 1 are also placed along the curved face portions of the holding plate 3 so as to prepare the holding plate 3 having the annular shaped curved face portion and a plurality of curved face portions (Third Embodiment).

As shown in FIGS. 1 to 5, each of the sample holding tools 100 to 102 according to the embodiment is provided with a holding plate 3 having curved face portions with which tip portions 1a of the convex portions 1 are made in contact, placed on its lower face concave portion, so that the sample is supported by the upper face convex portions of the curved face portions of the holding plate 3.

The base plate 2, which forms one component of these sample holding tools 100 to 102, is comprised of a plate member having a round shape or a polygonal shape, and desirably comprised of a ceramic body, such as, in particular, an alumina-based sintered body, a yttria-based sintered body, a YAG-based sintered body or a silicon nitride-based sintered body. In the case when the sample holding tool of the present invention is mounted on a sample suction device that is used for carrying out a film-forming process and an etching process on a sample of a semiconductor or liquid crystal by the use of a corrosive gas and a plasma thereof, the sample holding tool, when comprised of a ceramic body, such as a yttria-based sintered body, an alumina-based sintered body or a YAG-based sintered body, is allowed to have high corrosive resistant property and plasma resistant property, even upon exposure to the corrosive gas and plasma thereof.

The convex portions 1, which are formed so as to protrude from the upper face of the base plate 2, are periodically placed with virtually equal intervals in a predetermined one direction and in directions intersecting with this direction, and since the holding plates 3 are formed at the same positions with virtually equal intervals in the same manner, a sample, which is supported on the holding plates 3, becomes free from local distortions and deformations so that the sample can be held in a stable manner.

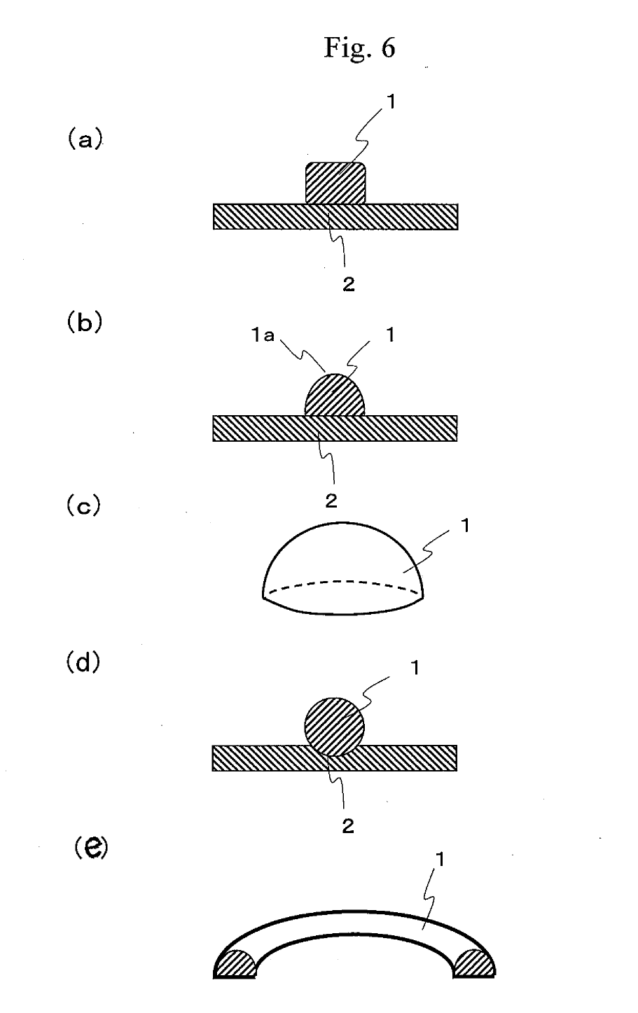

Referring to FIG. 6, the following description will discuss the shape of the convex portions 1 in detail. FIGS. 6(a) and 6(b) are cross-sectional views of the convex portions 1, taken along a direction perpendicular to the main face of the base plate 2, and it is only necessary for each convex portion 1 to have a spherical shape or a curved face shape at the portion to be made in contact with each holding plate 3 placed on the upper side thereof, and since the convex portions 1 and the holding plates 3 are made in contact with each other in a contact state close to a point contact so that the contact area between the holding plates 3 and the sample can be made smaller, with less frictional contact to the sample; thus, it becomes possible to restrain generation of particles due to abrasion.

As shown in FIG. 6(b), each convex portion 1 is desirably formed into a spherical shape, at least, in its tip portion 1a, in the cross-sectional view thereof. With this structure, the contact area with the holding plate 3 placed on the upper side of the convex portion 1 is made further smaller so that it becomes possible to further restrain generation of particles due to abrasion with the sample.

Moreover, as shown in FIG. 6(c), the convex portion 1 is desirably formed into a spherical cap shape. Here, the spherical cap shape in the present invention refers to a virtually semi-spherical body formed by cutting one portion of a sphere off in a diameter direction as shown in FIG. 6(c), and it is only necessary for this shape to have a spherical shape at the portion to be made in contact with the holding plate 3.

As shown in FIG. 6(d), each of the convex portions 1 may be formed as a spherical body, and in this case, a plurality of holes may be formed on the main face on the upper face side of the base plate 2 so that the spherical body may be held on each of the holes by using a bonding agent.

Moreover, as shown in FIG. 6(e), the convex portion 1 may be formed into an annular shape, and in this case, as will be described later, the holding plate 3 is formed so as to be made in contact with the annular shaped convex portion 1, as will be described later.

The convex portion 1, which is comprised of a ceramic body, such as an alumina-based sintered body, a yttria-based sintered body, a YAG-based sintered body and a silicon nitride-based sintered body in the same manner as in the base plate 2, may be formed as a part separated from the ceramic body forming the base plate 2, or may be formed as an integral part thereof, and by forming this using the same ceramic body as that of the base plate 2, it is possible to alleviate concentration of a stress caused by a difference in thermal expansion coefficients upon application of heat.

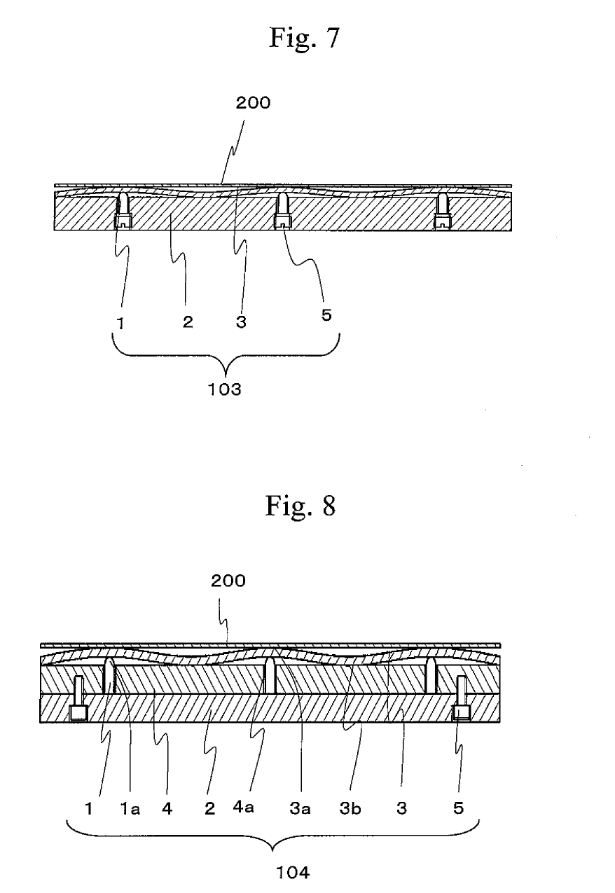

Moreover, as shown in a sample holding tool 103 in FIG. 7, the convex portions 1 may have a structure to be fastened to a plurality of through holes formed in the base plate 2 with screws 5. With this arrangement, the height of the convex portions 1 can be easily adjusted (Fourth Embodiment).

The holding plate 3, which is properly selected depending on applications of the sample holding tools 100 to 103, is desirably comprised of a ceramic body. Since the ceramic body is superior in corrosion resistance and abrasion resistance in comparison with metals and resins, it becomes possible to reduce the holding plate 3 from being worn out due to friction with the sample 200, and consequently to reduce generation of particles. Among such ceramic bodies, in particular, monocrystal or amorphous ceramic bodies are preferably used. Since the monocrystal or amorphous ceramic bodies have a microstructure, and contain no minute crystal grains, it is possible to reduce generation of particles caused by coming off of the crystal grains. Here, in the case of a ceramic body of a polycrystal structure, since a minute structure having crystal grains and grain interfaces or grain interface phases in a mixed state is formed, there is a difference in grinding resistance between the portion of crystal grains and the grain interface portion or the grain interface phase portion, upon carrying out a grinding process, with the result that fine irregularities tend to be formed even when the same grinding process is carried out; in contrast, in the case of the monocrystal or amorphous ceramic body, since a single microstructure is formed, a holding member 3 having a smoother surface can be easily obtained. Moreover, since a mono-crystal ceramic body has no lattice defects, and since the strength thereof is stable, it is possible to easily control safety against rupturing when the curvature of the convex portion 1 is made smaller, and since it is chemically stable, intrusion and dispersion of impurities into the sample 200 can be reduced. Moreover, the mono-crystal ceramic body makes it possible to reduce impurities from being mingled and dispersed therein during manufacturing processes. Among such mono-crystal materials, sapphire (mono-crystal of aluminum oxide) or the like is preferably selected because of its superior processability and mechanical properties when used as the holding plate 3. The sapphire has superior mechanical properties, that is, about 700 MPa in three-points bending strength and about 500 MPa in Young's modulus, and has such a property that even when deformed into a curved line shape, it is hardly subjected to cracking, rupturing or the like.

Here, the holding plate 3 is placed on the upper face side of respective convex portions 1 on the base plate 2, and as shown in cross-sectional views of FIGS. 2, 3 and 5, has a plurality of curved face portions corresponding to the convex portions 1, and it is only required for the lower face concave portions of the curved face portions to be made in contact with the tip portions 1a of the convex portions 1, and it is not necessarily required for them to be made in contact with the side face of each of the convex portions 1. Moreover, as shown in FIGS. 1, 2, 4 and 5, in the case of the sample holding tools 100 to 102 having one holding plate 3, the curved face portions of the holding plate 1 may be deformed by the convex portions 1. In this case, it is only necessary to form at least two contact portions 3b between each of the lower face concave portions of the curved portions of the holding plate 3 and the upper face of the base plate 2, and more preferably, the holding plate 3 is desirably formed into a disc shape with a plurality portions on the peripheral edge portion being formed as contact portions 3b. With this arrangement, it becomes possible to reduce particles to be generated in an area surrounded by the holding plate 3 and the base plate 2 from scattering outward.

As shown in FIGS. 1, 2, 4 and 5, in the case when the holding plate 3 has virtually the same size as that of the base plate 2, in order to allow a tensile strength that causes a separation at the contact portions 3b between the holding plate 3 and the base plate 2 to be equally exerted, the concave portions 1 and the contact portions 3b are desirably placed so that the distance between each concave portion 1 and each contact portion 3b is made virtually equal to each other at each of the portions, and for the same reason, the peripheral edge portion of the holding plate 3 is more preferably formed into the contact portions 3b.

The joining process of the holding plate 3 and the convex portions 1 may be carried out by injecting a joining material made from a bonding agent made of resin into the void portions formed by the convex portions 1 and the holding plate 3. Thus, the holding plate 3 can be secured to the convex portions 1, and since the voids formed by the convex portions 1 can be filled with the joining material so that it becomes possible to reduce the holding plate 3 from being deformed, and also to allow heat generated by the sample thus held to be transmitted to the other members such as a guide plate, which will be described later, through the holding plate 3. Examples of the bonding agent made from resin include silicon-based, polyimide-based or epoxy-based bonding agents.

Moreover, in the case when there are a plurality of holding plates 3, as shown in FIG. 3, after each of them has been processed into a curved face shape, the resulting holding plate 3 may be made in contact with each convex portion 1; however, after having been formed into a plane shape, the holding plate 3 is desirably processed into a curved face shape by joining it to the base plate 2 while being made in contact with each of the convex portions 1. With this process, the processing becomes easier, in comparison with the processes in which it is preliminarily formed into a curved face shape, and the height and position of the tip portion 3a of the curved face portion to support the sample can be controlled by the convex portions 1.

As shown in FIG. 2, the holding plate 3 is preferably designed to have the curvature radius R1 of the lower face concave portion in the curved face portion that is made larger than the curvature radius R2 of the tip portion 1a of the convex portion 1; thus, each convex portion 1 and the holding plate 3 can be made in point-contact with each other so that the height of the holding plate 3 can be controlled with high precision. Moreover, the curvature radius of each curved face portion of the holding plate 3 at the tip portion 3a of the upper face convex portion is desirably made smaller than the curvature radius of the tip portion 3a caused by distortion due to the self-weight and a suction force of the sample 200.

As shown in FIGS. 1, 2, 4 and 5, when the holding plate 3 is formed into a single plate member with a plurality of curved face portions, the effects of the present invention are obtained without the necessity of taking the surface treatment of the base plate 2 and the face state of the surface into consideration.

Moreover, the surface roughness of at least the upper side main face (face on the side supporting the sample) of the holding plate 3 is desirably set to 0.2 μm or less in the average interval (S) of local peaks.

This arrangement is made because, at present, since the pattern width of the circuit wiring of a semiconductor is miniaturized to 100 nm or less, adhesion of particles of about 0.2 μm to the sample 200 during manufacturing processes tends to cause serious problems to a finished semiconductor circuit, such as maloperation. For this reason, the average interval (S) of local peaks corresponding to the surface roughness of at least the upper side main face of the holding plate 3 is desirably set to 0.2 μm or less so that particles of 0.2 μm or more are reduced from intruding into the concave/convex portions of the holding plate 3. Here, the average interval (S) of local peaks is preferably set to 0.04 μm or less, more preferably, to 0.03 μm or less. Moreover, in the case when the surface roughness of at least the upper side main face of the holding plate 3 is set to 0.2 μm or less in the maximum height (Rz), since particles can be suppressed from intruding into fine concave/convex portions of the holding plate 3, it is possible to provide a desirable structure. Here, the above-mentioned average interval (S) of local peaks is measured to be found in accordance with JIS B 0601-1994, and the maximum height (Rz) is measured to be found in accordance with JIS B 0601-2001.

The thickness of the holding plate 3 is preferably set in a range from 10 μm or more to 200 μm or less. The thickness of the holding plate 3 of less than 10 μm tends to cause a crack in the holding plate 3, when the holding plate 3 comes into contact with the convex portion 1 or when it is made in contact with the convex portion 1 to be supported thereon. Moreover, in an attempt to obtain a holding plate 3 as thin as 10 μm, a manufacturing process with high precision is required to cause high processing costs. Here, the thickness of the holding plate 3 exceeding 200 μm makes it difficult to form the holding plate 3 into an appropriate curved face.

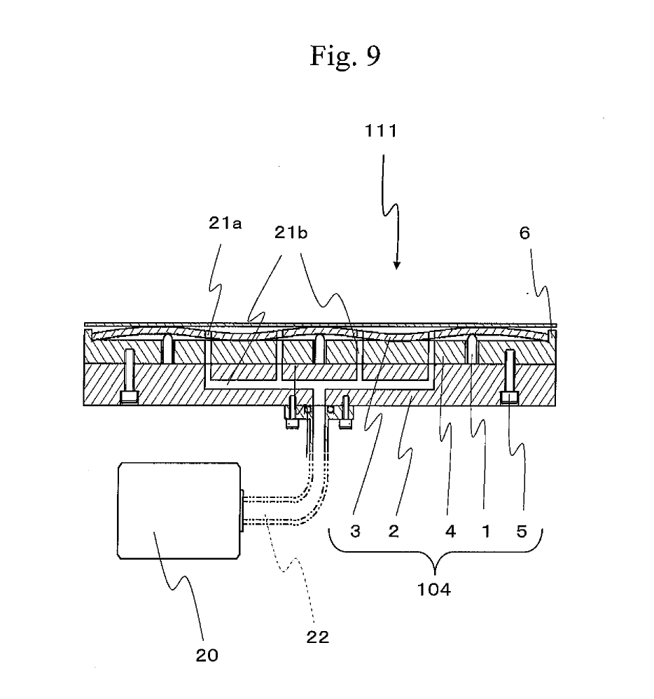

Referring to FIG. 8, the following description will discuss a sample holding tool in accordance with a fifth embodiment of the present invention.

FIG. 8 is a cross-sectional view that shows a state in which a sample 200 is placed on a sample holding tool 104 in accordance with the fifth embodiment of the present invention, and the sample holding tool 104 has a structure in which a guide plate 4 having a plurality of through holes 4a corresponding to the convex portions 1 is placed on the main face on the upper face side of the base plate 2 in each of the sample holding tools 100 to 103, shown in FIGS. 1 to 5. The guide plate 4 and the base plate 2 are fastened to each other with screws 5.

The guide plate 4 is preferably comprised of the same ceramic body as the ceramic body forming the base plate 2. By installing the guide plate 4, it is possible to easily adjust the height of the tip portion 1a of the convex portion 1 formed on the main face on the upper side of the base plate 2 to various heights evenly. That is, in the case when each of the convex portions 1 is formed on the main face on the upper side of the base plate 2, as shown in FIGS. 1 to 5, it is necessary to carry out a grinding process or the like so as to evenly make the height from the main face on the upper side of the base plate 2 to the tip portion 1a of the convex portion 1; however, the present sample holding tool 104 makes it possible to adjust the height of the convex portion 1 easily by adjusting the height of the base plate 2 relative to the guide plate 4 by using screws 5 or the like, and the flatness can be easily controlled by adjusting the heights of the respective screws 5.

### (Manufacturing Method)

Here, the following description will discuss a manufacturing method for the sample holding tool of the present invention.

Upon forming each of the sample holding tools 100 to 102, a ceramic body used for forming the base plate 2 is prepared, and convex portions 1 are formed on the upper face of this ceramic body. The convex portions 1 may be joined to the upper face of the base plate 2, or the upper face of the base plate 2 may be subjected to a blasting process or the like so that the convex portions 1 are integrally formed. Here, in order to align the heights of the tips of the convex portions 1, the tips of the convex portions 1 are preferably subjected to a grinding process. Next, the holding plate 3, comprised of the ceramic body, is subjected to a grinding process so as to have proper flatness, surface roughness and thickness, and is then placed on the upper main face of the base plate 2 provided with the convex portions 1. At this time, the joining process of the holding plate 3 and the convex portions 1 or the base plate 2 may be carried out by using, for example, polyimide resin. In particular, in the case of the sample holding tool 101 in which a plurality of holding plates 3 are used, a contact portion 3b to the base plate 2 may be formed on the peripheral edge portion of the holding plate 3.

With respect to the method for preliminarily processing the holding plate 3 into a shape having curved face portions, a method is proposed in which after an appropriate place of one face or two faces of the holding plate 3 has been masked, this is subjected to a blasting process, or another method is proposed in which a metal mold or the like is used for molding or polishing it into a predetermined shape. Moreover, in order to reduce generation of particles or the like, top faces of the convex portions formed on the surface used for supporting the sample 200 are preferably polished by using abrasive grains and the like. Here, the rear face of the supporting face of the sample 200 of the holding plate 3, that is, the lower face concave portion of the curved face portion is made in contact with the convex portion 1 so that a contact portion 3b may be formed at a desired place of the base plate 2 so that the holding plate 3 may be formed into a curved face shape. At this time, the holding plate 3 and the base plate 2 are preferably joined to each other by using polyimide resin or the like.

In the case of a sample holding tool 103 in accordance with the fourth embodiment, a base plate 2 having a through hole 2a formed from the upper face toward the lower face is prepared, and a holding plate 3 is placed on the upper face of the base plate 2. At this time, an appropriate portion of the holding plate 3 is joined to the base plate 2 by using polyimide resin or the like. In the case when a plurality of holding pates 3 are used, a contact portion 3b to the base plate 2 may be formed on the peripheral edge portion of the holding plate 3. Next, a convex portion 1 is prepared. The convex portion 1 is preferably comprised of a ceramic body in the same manner as in the base plate 2. The convex portion 1 is inserted to the through hole 2a of the base plate 2 so that the convex portion 1 is raised by a screw 5. At this time, the tip of the convex portion 1 is allowed to stick out of the upper face of the base plate 2 so that the tip of the convex portion 1 sticking out from the upper face of the base plate 2 raises the holding plate 3 preliminarily placed thereon; thus, the holding plate 3 is formed into a curved line shape.

In a method for manufacturing a sample holding tool 104 in accordance with the fifth embodiment, a guide plate 4 having a through hole 4a formed from the upper face toward the lower face is prepared, and a holding plate 3 is placed on the upper face of the guide plate 4. At this time, an appropriate portion of the holding plate 3 is joined to the guide plate 4 by using polyimide resin or the like. In the case when a plurality of holding plates 3 are used, a contact portion 3b to the base plate 2 is formed on the peripheral edge portion of the holding plate 3. Next, a base plate 2 and a convex portion 1 having a flat shape are prepared. Here, the convex portion 1 is preferably comprised of a ceramic body in the same manner as in the base plate 2. The convex portion 1 is inserted to the through hole 4a of the guide plate 4, and the base plate 2 is fastened to the lower face of the guide plate 4 with a screw 5. At this time, the tip of the convex portion 1 is allowed to stick out of the upper face of the guide plate 4 so that the tip of the convex portion 1 sticking out from the upper face of the guide plate 4 is allowed to raise the holding plate 3 preliminarily placed thereon; thus, the holding plate 3 is formed into a curved line shape.

### (Sample Suction Device)

Referring to FIG. 9, the following description will discuss a sample suction device that uses the sample holding tool of the present invention, manufactured as described above.

FIG. 9 is a cross-sectional view that shows a sample suction device which uses the sample holding tool of the present invention. The sample suction device 111 of the present invention is provided with a seal portion 6 that is used for forming spaces tightly-sealed between the sample 200 to be held and the holding plate 3, and placed on the outer edge portion of the upper main face of the guide plate 4 of the sample holding tool 104, and when this structure is further provided with an evacuation means 20 used for evacuating the spaces, it is possible to hold the sample 200 by using a pressure difference generated between the upper and lower portions of the sample 200 by the suction force. In this case, the sample 200 and the seal portion 6 are not necessarily made in contact with each other, and from the viewpoint of generation of particles due to friction between the sample 200 and the seal portion 6, it is preferable to place a gap to such a degree as to provide the sufficient pressure difference to suck the sample 200 during the processes.

Moreover, the guiding plate 4 and the base plate 2 have evacuation holes 21b that are connected to the evacuation means 20, and the holding plate 3 also has evacuation holes 21a in the same manner. Here, the evacuation means 20 is connected to the evacuation holes 21b through an evacuation pipe 22 comprised of a rubber hose or a thin flex tube, and a vacuum pump, such as a dry pump or a diaphragm pump, is used as the evacuation means.

Here, the present sample suction device 111 has been explained by using the sample holding tool 104; however, the sample holding tools 100 to 103 may be used. In this case, however, the base plate 2 of each of the sample holding tools 100 to 103 needs to be provided with a seal portion 6 on the outer edge portion in the same manner as described above.

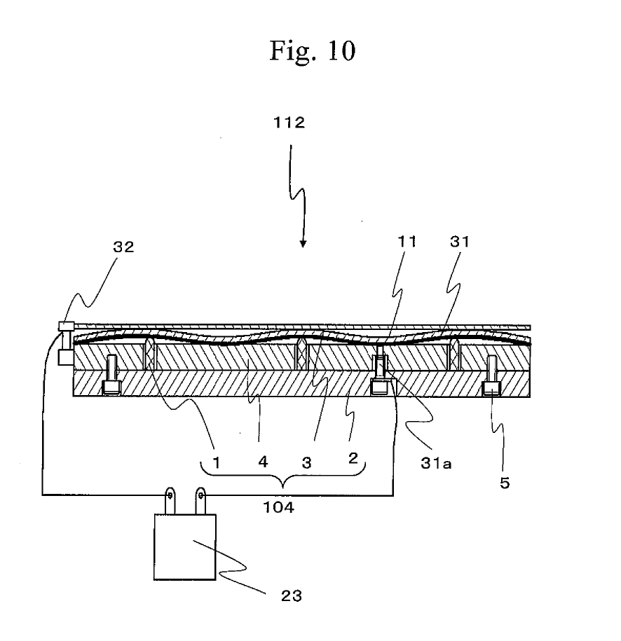

Referring to FIG. 10, the following description will discuss a sample suction device in accordance with another embodiment, which uses the sample holding tool 104 of the present invention. This sample suction device 112 is preferably used, for example, when the sample 200 is made from a conductive material, as well as when the ambient atmosphere of the sample 200 has a low pressure, with the result that the aforementioned sample suction device 111 fails to provide a sufficient pressure difference to hold the sample 200.

The sample suction device 112 of the present invention has a structure in which an electrode unit 31 is placed on the face of the holding plate 3 on the guide plate 4 side of the sample holding tool 104 and a voltage is applied by an electrode take-out unit 32 attached to the guide plate 4 so that the sample 200 can be sucked by an electrostatic force generated between the sample 200 and the holding plate 3.

In this case, the sample 200 can be sucked in the following two ways: that is, a so-called “bipolar type” in which, while no electric potential is applied to the sample 200, the electrode unit 31, placed on the back face of the holding plate 3, is divided into two portions, with different electric potentials being applied to the respective portions, and a so-called “monopolar type” in which only a single electrode is placed on the back face of the holding plate 3, and an electrode unit 32 is also placed on the sample 200 so that an electric potential is applied. Here, in FIG. 10, only the monopolar type is explained; needless to say, the bipolar type is of course applicable. Moreover, the electrode unit 31 is easily formed by coating metal such as titanium, through vapor deposition, plating or CVD, and the electrode unit 32 is preferably placed as bearings made from a conductive material so as to reduce frictional abrasion with the sample 200. Moreover, in the case when the sample suction device 112 of the present invention is used for a process in which plasma is used, in order to protect the electrode unit 31, it is effective to film-form yttria or the like having a plasma resistant property on a portion of the electrode unit 31 other than a contact portion to the electrode take-out unit 31a.

### (Sample Processing Method)

As described above, the sample holding tool 104 and the sample suction devices 111 and 112 of the present invention can be applied to a process in which a sample 200 is suction-placed on the holding plate 3 and processes in which the sample 200 is subjected to an inspection, pattern-drawing, exposing, resist-applying, or etching treatment as well as a thin-film forming treatment by CVD. Moreover, the sample suction device 112 that carries out a suction process by using an electrostatic force can be applied to processes that are carried out in vacuum. Furthermore, when used for pattern-drawing, exposing and inspection processes, a high degree of flatness is required for the sample 200; therefore, a number of convex portions 1 are preferably formed on the base plate 2 so as to reduce distortion or the like from occurring in the sample 200, and the number thereof is properly selected depending on the thickness and size of the sample 200.

1. A sample holding tool comprising:
a base plate;
a plurality of convex portions formed on the base plate so as to stick out from the upper face thereof; and
at least one holding plate having a plurality of curved face portions corresponding to the convex portions, with a lower face concave portion of each of the curved face portions being made in contact with the tip portion of each of the convex portions, so that a sample is supported on the upper face convex portion of each of the curved face portions.

2. The sample holding tool according to claim 1, wherein a guide plate having a plurality of through holes corresponding to the convex portions is placed on the upper face of the base plate.

3. The sample holding tool according to claim 1, wherein the base plate and the holding plate are provided with evacuation holes that communicate with a space between the sample and the holding plate.

4. The sample holding tool according to claim 2, wherein the base plate, the holding plate and the guide plate are provided with evacuation holes that communicate with a space between the sample and the holding plate.

5. The sample holding tool according to claim 1, wherein a void portion, formed by the convex portion and the holding plate, is filled with a joining material.

6. The sample holding tool according to claim 1, wherein the lower face concave portion of each of the curved face portions of the holding plate has a curvature radius that is larger than the curvature radius at the tip portion of each of the convex portions.

7. The sample holding tool according to claim 1, wherein the convex portion has an arc shaped cross section in at least the tip portion thereof.

8. The sample holding tool according to claim 7, wherein the convex portion has a spherical cap shape.

9. The sample holding tool according to claim 7, wherein the convex portion has an annular shape.

10. The sample holding tool according to claim 1, wherein the holding plate has a surface roughness of 0.2 mm or less in the average interval (S) of local peaks at least on the surface on the side supporting the sample.

11. The sample holding tool according to claim 1, wherein the holding plate is comprised of a monocrystal or amorphous ceramic body.

12. The sample holding tool according to claim 1, wherein the base plate is comprised of a ceramic body.

13. The sample holding tool according to claim 1, wherein the convex portion is comprised of a ceramic body.

14. A sample suction device, which uses the sample holding tool according to claim 1, comprising:
a seal portion that is placed on an outer edge of the base plate upper face, and used for forming a tightly closed space between the sample and the holding plate; and
evacuation means for evacuating the space,
wherein the sample is sucked by a pressure difference from the outside of the space.

15. A sample suction device, which uses the sample holding tool according to claim 1, comprising:
an electrode unit formed on the surface on the base plate side of the holding plate,
wherein the sample is sucked by an electrostatic force generated between the holding plate and the sample.

16. A sample processing method, which uses the sample suction device according to claim 14 or 15, comprising the steps of:
sucking the sample so as to be placed on the holding plate, and
carrying out a process, such as etching or film-forming, on the sample.
